(19) United States
(12) Patent Application Publication
(10) Pub. No.: US 2015/0048413 A1
(43) Pub. Date: Feb. 19, 2015

(54) SEMICONDUCTOR DEVICE

(71) Applicant: DENSO CORPORATION, kariya-city, Aichi-pref. (JP)

(72) Inventors: Kazuki Arakawa, Toyoake-city (JP); Masakiyo Sumitomo, Okazaki-city (JP); Masaki Matsui, Nagoya-city (JP); Yasushi Higuchi, Okazaki-city (JP)

(21) Appl. No.: 14/386,132

(22) PCT Filed: May 13, 2013
(86) PCT No.: PCT/JP2013/003037

§ 371 Date: Sep. 18, 2014

(30) Foreign Application Priority Data
May 31, 2012 (JP) 2012-124955

(51) Int. Cl. H01L 29/739; H01L 29/423; H01L 29/78; H01L 29/10

(52) U.S. Cl. CPC H01L 29/7397; H01L 29/1095; H01L 29/4236; H01L 29/7813
USPC 257/139

(57) ABSTRACT

A semiconductor device includes: a drift layer; a base layer arranged in a surface portion of the drift layer; multiple trenches penetrating the base layer and reaching the drift layer; and a gate electrode arranged on the gate insulation film in each trench. Each trench includes: a first trench having an opening on a surface of the base layer; and a second trench connecting the first trench and having a portion, of which a distance between facing sidewalls of the second trench is longer than a distance between facing sidewalls of the first trench. The opening of each first trench is sealed with the gate electrode. An inside of each gate electrode includes a cavity portion.

### CROSS REFERENCE TO RELATED APPLICATION

This application is based on Japanese Patent Application No. 2012-124955 filed on May 31, 2012, the disclosure of which is incorporated herein by reference.

### TECHNICAL FIELD

The present disclosure relates to a semiconductor device having a trench gate structure.

### BACKGROUND ART

Conventionally, a semiconductor device having a trench gate structure is well known. For example, a semiconductor device, in which an insulated gate bipolar transistor (i.e., IGBT) having the trench gate structure is formed, is proposed (for example, please refer to Patent Literature No. 1).

Specifically, in the above semiconductor device, a drift layer having a N− conductive type is formed on a collector layer having a P+ conductive type. A base layer having the P conductive type is formed in a surface portion of the drift layer. An emitter layer having the N+ conductive type is formed in a surface portion of the base layer. Further, multiple trenches are arranged in a stripe pattern such that each trench penetrates the base layer and the emitter layer and reaches the drift layer. A gate insulation film made of a oxide film is formed on a sidewall of each trench. A gate electrode made of doped poly silicon or the like is formed on the gate insulation film so as to fill an inside of the trench. Thus, a trench gate structure is provided.

The emitter electrode is formed on the base layer and the emitter layer via n interlayer insulation film. The base layer and the emitter layer are electrically connected to the emitter electrode via a contact hole, which is formed in the interlayer insulation film. Further, a collector electrode electrically connecting to the collector layer is disposed on the backside of the collector layer.

However, in the above semiconductor device, for example, when the gate electrode is formed, or when the temperature in the usage environment is changed to be high, a stress attributed to a difference between a linear coefficient expansion of the gate insulation film and a linear coefficient expansion of the gate electrode is generated. Accordingly, the trench gate structure is damaged by the stress, and therefore, a difficulty may arise such that the characteristics are deteriorated, and the reliability of the gate insulation film is reduced.

Here, the above difficulty may arise not only in the semiconductor device, in which the N channel IGBT is formed, but also in the semiconductor device, in which the P channel IGBT is formed. Similarly, the above difficulty may arise in a trench gate type MOSFET without a collector layer.

### PRIOR ART LITERATURES

### Patent Literature

Patent Literature 1: JP-A-2006-351924

### SUMMARY OF INVENTION

It is an object of the present disclosure to provide a semiconductor device having a trench gate structure, in which a stress generated at the trench gate structure is reduced.

According to an example aspect of the present disclosure, a semiconductor device includes: a drift layer having a first conductive type; a base layer having a second conductive type and arranged in a surface portion of the drift layer; a plurality of trenches penetrating the base layer, reaching the drift layer, and arranged in a predetermined direction; a gate insulation film arranged on a sidewall of each trench; and a gate electrode arranged on the gate insulation film, respectively. Each trench includes: a first trench having an opening on a surface of the base layer; and a second trench connecting the first trench and having a portion, of which a distance between facing sidewalls of the second trench is longer than a distance between facing sidewalls of the first trench. The opening of each first trench is sealed with the gate electrode. An inside of each gate electrode includes a cavity portion.

In the above semiconductor device, when the gate electrode is formed, or when the temperature of a usage environment is changed to be high, the stress is reduced by the cavity portion even if the stress attributed to the difference between the linear coefficient expansion of the gate insulation film and the linear coefficient expansion of the gate electrode is generated. Accordingly, the deterioration of the characteristics of the trench gate structure and the reduction of the reliability are restricted.

### BRIEF DESCRIPTION OF DRAWINGS

The above and other objects, features and advantages of the present disclosure will become more apparent from the following detailed description made with reference to the accompanying drawings. In the drawings:

FIG. 1 is a cross sectional view of a semiconductor device according to a first embodiment;

FIG. 2(a) to FIG. 2(d) are cross sectional views showing a manufacturing process of the semiconductor device shown in FIG. 1;

FIG. 3(a) to FIG. 3(d) are cross sectional views showing the manufacturing process of the semiconductor device following FIG. 2(d);

FIG. 4 is a cross sectional view of a semiconductor device according to a second embodiment;

FIG. 5(a) to FIG. 5(c) are cross sectional views showing a manufacturing process of the semiconductor device shown in FIG. 4;

FIG. 6(a) to FIG. 6(c) are cross sectional views showing the manufacturing process of the semiconductor device following FIG. 5(c);

FIG. 7 is a cross sectional view of a semiconductor device according to a third embodiment; and

FIG. 8 is a cross sectional view of a semiconductor device according to a fourth embodiment.

### EMBODIMENTS FOR CARRYING OUT INVENTION

### First Embodiment

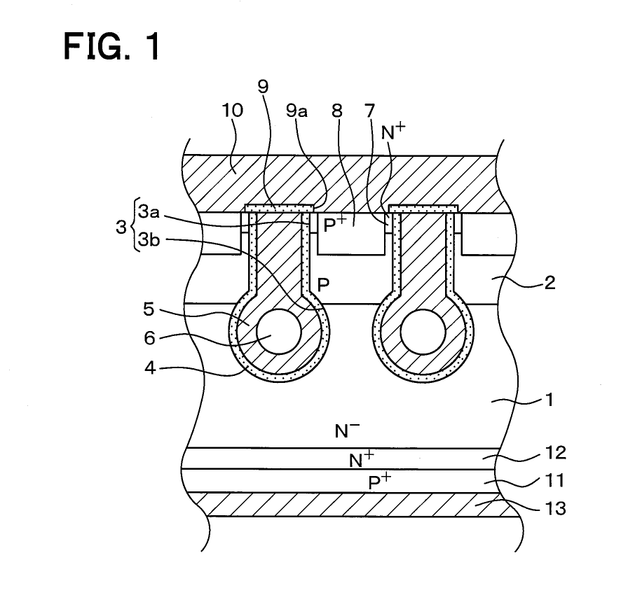

A first embodiment of the present disclosure will be explained with reference to drawings. As shown in FIG. 1, in a semiconductor device according to the present embodiment, a IGBT having a trench gate structure is formed.

The semiconductor device includes a drift layer 1 having a N− conductive type. A base layer 2 having a P conductive type is formed in a surface portion of the drift layer 1. Further, multiple trenches 3 are arranged to have a stripe pattern along a predetermined direction (i.e., a vertical direction of the drawing in FIG. 1) such that each trench 3 penetrates the base layer 2 and reaches the drift layer 1.

Here, in this embodiment, a case where multiple trenches 3 have the stripe structure is explained. Alternatively, multiple trenches 3 may have a ring structure such that multiple trenches 3 are arranged to be in parallel to each other, and then, top ends of the trenches 3 are bended and connected to each other.

Each trench 3 includes a first trench 3a formed in the base layer 3, and a second trench 3b coupling with the first trench 3a and reaching from a boundary between the base layer 2 and the drift layer 1 to the drift layer 1. Specifically, the second trench 3b in the present embodiment is formed from the base layer 2 to the drift layer 1. A connection portion between the first trench 3a and the second trench 3b is disposed in the base layer 2.

The second trench 3b has a circle shape having a portion, of which a distance between facing sidewalls (i.e., a length in a right-left direction of the drawing in FIG. 1) is longer than a distance between facing sidewalls of the first trench 3a (i.e., a length in a right-left direction of the drawing in FIG. 1), in the cross section of FIG. 1. Thus, the second trench 3b has a shape such that a bottom and a sidewall are rounded (i.e., has a shape with a curvature). Accordingly, the trench 3 has a urceolate shape in the cross section of FIG. 1.

Here, a portion of the second trench 3b having the longest distance between facing sidewalls is disposed in the drift layer 1. Further, each trench 3 has the connection portion between the first trench 3a and the second trench 3b, which has a rounded shape (i.e., a curvature shape).

A gate insulation film 4 made of thermally-oxidized film or the like is formed on a sidewall of each trench 3. The gate electrode 5 made of conductive material such as doped poly silicon is formed on the gate insulation film 4 so that an opening is closed. In the present embodiment, the trench 3, the gate insulation film 4 and the gate electrode 5 provide the trench gate structure.

The gate electrode 5 is formed to have a uniform thickness in the second trench 3b. A cavity portion 6 is formed along the sidewall of the second trench 3b in the second trench 3b. Thus, the cavity portion 6 having a circular cross sectional shape is formed in the gate electrode 5. The gate electrode 5 completely fills the first trench 3a.

The emitter layer 7 having the N+ conductive type is formed on the sidewall of the first trench 3a in the surface portion of the base layer 2. A contact layer 8 having the P+ conductive type and a concentration higher than the base layer 2 is formed in the surface portion of the base layer 2, which is disposed between the adjacent first trenches 3a opposed to the first trench 3a through the emitter layer 7, and faces the drift layer 1 disposed between the adjacent second trenches 3b. In other words, the contact layer 8 is formed in the surface portion of the base layer 2 immediately above the drift layer 1 disposed between the second trenches 3b.

The emitter electrode 10 is formed on the surface of the emitter layer 7, the surface of the contact layer 8 and the surface of the gate electrode 5 via an interlayer insulation film 9. The emitter electrode 10 is electrically connected to the emitter layer 7 and the contact layer 9 via a contact hole 9a formed in the interlayer insulation film 9.

Further, a collector layer 11 having the P+ conductive type is formed on the backs side of the drift layer 1. A buffer layer 12 having the N+ conductive type is formed between the drift layer 1 and the collector layer 11. The buffer layer 12 is not always necessary to form. The buffer layer 12 is provided in order to prevent an expansion of a depletion layer so that a performance of the withstand voltage and the stationary loss is improved. A collector electrode 13 is formed on the backside of the collector layer 11, and the collector electrode 13 is electrically connected to the collector layer 11.

The structure of the semiconductor device according to the present embodiment is described above. Here, in the present embodiment, the N+ conductive type and the N− conductive type correspond to a first conductive type. The P conductive type and the P+ conductive type correspond to a second conductive type.

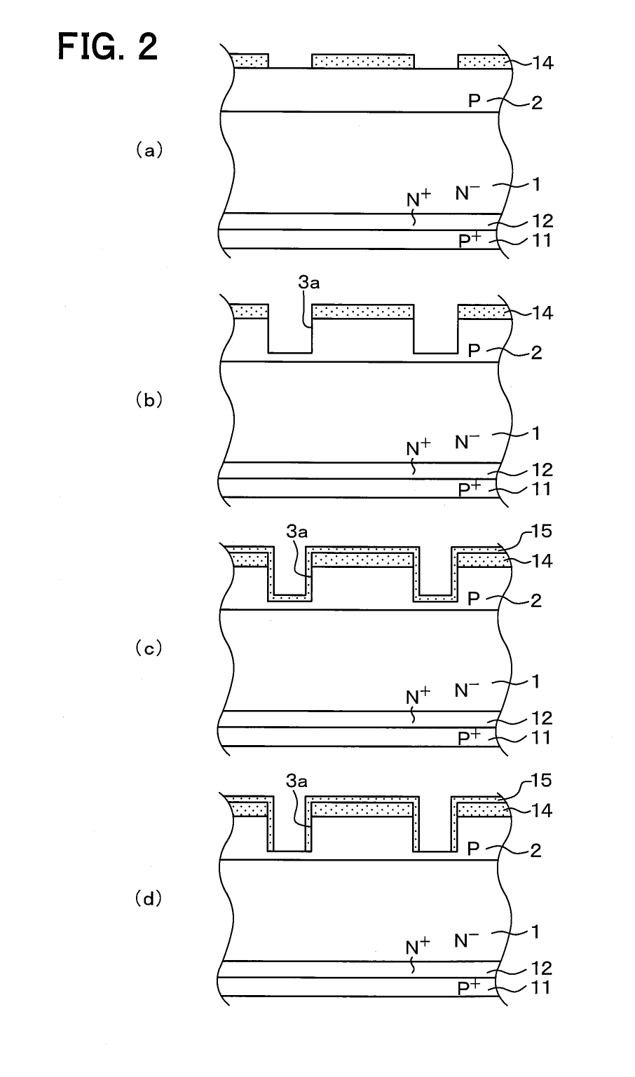

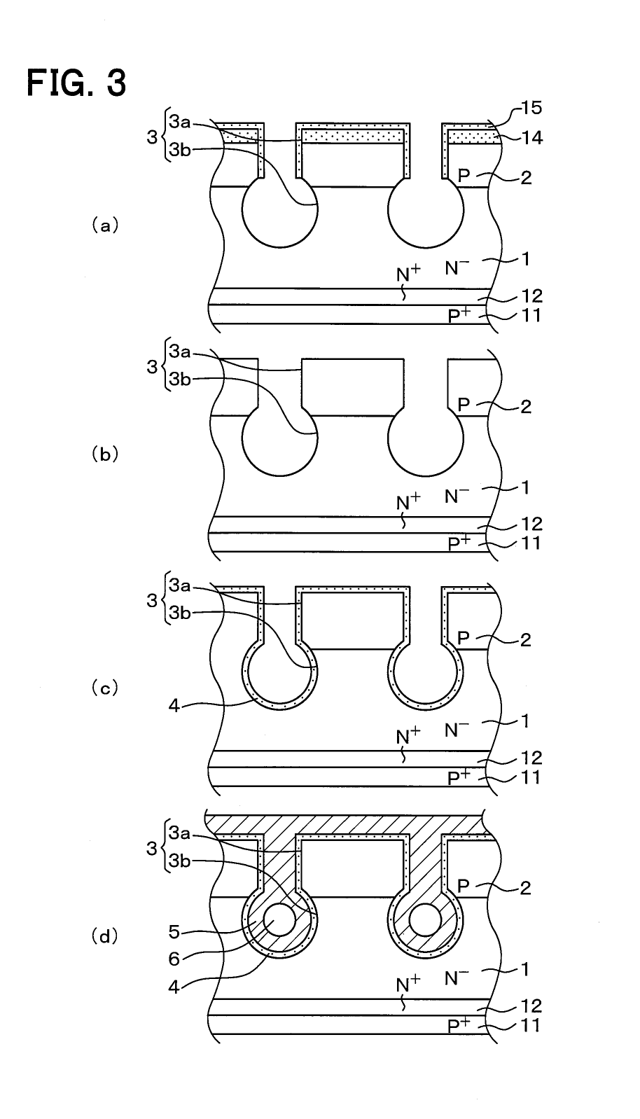

A manufacturing method for the above semiconductor device will be explained with reference to FIGS. 2(a) to 2(d) and 3(a) to 3(d).

First, as shown in FIG. 2(a), a product is prepared such that the base layer 2 is formed on the front side of the drift layer 1, and the collector layer 11 and the buffer layer 12 are formed on the backside of the drift layer 1. For example, the base layer 2, the collector layer 11 and the buffer layer 12 are formed that an impurity is ion-implanted or the like, and then, the impurity is thermally diffused.

After that, an etching mask 14 made of a silicon oxide film is formed on the base layer 2 by a chemical vapor deposition (i.e., CVD) method or the like. The etching mask 14 is patterned so that a first-trench-3a-to-be-formed region of the etching mask 14 is opened.

Then, as shown in FIG. 2(b), the first trench 3a is formed by anisotropic-etching such as reactive ion etching (i.e., RIE) using the etching mask 14. In the present embodiment, since the first trench 3a has an end in the base layer 2 (i.e., the end of the first trench 3a opposite to the opening side is disposed in the base layer 2), the first trench 3a is formed near a boundary between the base layer 2 and the drift layer 1. After that, if necessary, chemical dry etching (i.e., CDE) or the like is performed, so that a step for removing a damage portion of the sidewall of the formed first trench 3a is performed.

Next, as shown in FIG. 2(c), the etching mask 15 made of a SiN film or the like is formed on the sidewall of the first trench 3a by the CVD method or the like. Here, in this step, the etching mask 14 remains without removing. Alternatively, after the etching mask 14 is removed, the etching mask 15 may be formed.

Then, as shown in FIG. 2(d), the anisotropic etching such as the RIE is performed, so that the etching mask 15 arranged on the bottom of the first trench 3a is selectively removed with remaining the etching mask 15 arranged on the sidewall of the first trench 3a.

Then, as shown in FIG. 3(a), using the etching mask 15, the isotropic etching is performed over the bottom of the first trench 3a. Thus, the second trench 3b is formed to have a portion, of which the distance between facing sidewalls is longer than the distance between the facing sidewalls of the first trench 3a. Thus, the trench 3 having the urceolate shape is formed.

Here, when the second trench 3b is formed by the isotropic etching, the connection portion between the first trench 3a and the second trench 3b, the bottom of the second trench 3b and the sidewall of the second trench 3b have a rounded shape. Thus, the cross sectional shape is a circular shape.

Then, as shown in FIG. 3(b), the etching masks 14, 15 are removed. Then, as shown in FIG. 3(c), the gate insulation film 4 is formed on the sidewall of the trench 3. The gate insulation film 4 is formed by, for example, a CVD method or a thermal oxidation method.

Next, as shown in FIG. 3(d), the gate electrode 5 is formed by depositing a film made of conductive material such as doped poly silicon on the gate insulation film 4 by the CVD method. In this case, the conductive material such as the doped poly silicon is deposited uniformly on the gate insulation film 4. Further, the second trench 3b has a circular shape with the portion, of which the distance between facing sidewalls is longer than the distance between the facing sidewalls of the first trench 3a.

Accordingly, when the conductive material such as the doped poly silicon is deposited by the CVD method, the first trench 3a is filled with the conductive material before the second trench 3b is completely filled with the conductive material. Thus, the cavity portion 6 is formed in the second trench 3b. Thus, when the trench 3 having the urceolate shape is formed, the cavity portion 6 is surely formed in the second trench 3b. Further, the gate electrode 5 is deposited on the sidewall of the second trench 3b via the gate insulation film 4 to have a uniform thickness. Thus, the cavity portion 6 has a shape along the sidewall of the second trench 3b.

Accordingly, an insulation film and a doped poly silicon film deposited on the base layer 2 are removed by performing a conventional manufacturing process of the semiconductor device. After that, the emitter layer 7, the contact layer 8, the interlayer insulation film 9, the emitter electrode 10, the collector electrode 13 and the like are formed. Thus, the semiconductor device shown in FIG. 1 is manufactured.

Here, when the emitter layer 7 and the contact layer 8 are formed by the ion implantation method, for example, an acceleration voltage in a case where an impurity for providing the emitter layer 7 and the contact layer 8 is ion-implanted is appropriately controlled, so that the contact layer 8 is formed at a position deeper than the emitter layer 7.

Thus, as described above, in the present embodiment, the cavity portion 6 is formed in the gate electrode 5. Accordingly, when the gate electrode 5 is formed, or when the temperature of the usage environment is changed to be high, the stress is reduced by the cavity portion 6 even if the stress attributed to the difference between the linear coefficient expansion of the gate insulation film 4 and the linear coefficient expansion of the gate electrode 5 is generated. Accordingly, the deterioration of the characteristics of the trench gate structure and the reduction of the reliability are restricted.

Further, the cavity portion 6 is formed in the second trench 3b. Accordingly, the stress attributed to the difference between the linear coefficient expansion of the gate insulation film 4 formed on the second trench 3b and the linear coefficient expansion of the gate electrode 5 formed on the second trench 3b is much reduced. Thus, a defect is restricted from being introduced in the drift layer 1, which contacts the second trench 3b. The leak current is restricted. Further, the stress generated at the bottom of the second trench 3b, at which the electric field is concentrated, is easily reduced. Thus, the reliability is improved.

Further, in the above semiconductor device, the portion of the second trench 3b, which has the longest distance between facing sidewalls, is disposed in the drift layer 1. Thus, the shortest distance between adjacent second trenches 3b among the distance between adjacent trenches 3 is shorter than the distance between adjacent first trenches 3a. Accordingly, compared with a case where the distance between adjacent trenches 3 is constant and equal to the distance between adjacent first trenches 3a, it is difficult for the hole supplied to the drift layer 1 to discharge from the drift layer 1 via the base layer 2. Accordingly, a large amount of holes is accumulated in the drift layer 1, and a total amount of electrons to be supplied to the drift layer 1 is also increased. The on-state resistance is reduced.

Further, since the cavity portion 6 is formed in the trench 3, the cavity can be utilized to a characteristic check of the semiconductor device. Specifically, for example, when a X ray is irradiated on the surface of the base layer 2, the strength of the transmitted beam is changed according to existence of the cavity portion 6. Further, the cavity portion 6 is formed such that the gate electrode 5 is deposited along the sidewall of the trench 3 to have the uniform thickness, and therefore, the cavity portion 6 has a shape along with the sidewall of the second trench 3b. Accordingly, when the state of the cavity portion 6 is detected, the shape of the sidewall of the second trench 3b is also detected. Thus, the distance between adjacent second trenches 3b is also detected. Thus, when the state of the cavity portion 6 is checked, the characteristics check of the semiconductor device such as an on-state voltage property is performed.

### Second Embodiment

A second embodiment of the present disclosure will be explained. In the present embodiment, the shape of the second trench 3b is changed, compared with the first embodiment. Other features are similar to the first embodiment. Thus, the other features are not explained here.

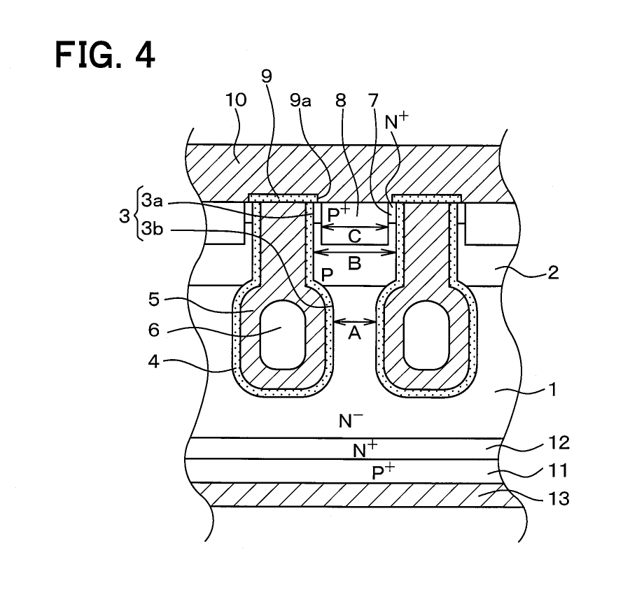

As shown in FIG. 4, in the semiconductor device according to the present embodiment, a part of the sidewall of the second trench 3b does not have a rounded shape. In other words, the part of the sidewall of the second trench 3b has a shape without a curvature. Thus, the part of the sidewall extends along a direction in parallel to the depth direction of the trench 3 (i.e., an up-down direction of the drawing in FIG. 4). The second trench 3b has a length in the depth direction of the trench 3 is longer than the second trench 3b in the first embodiment.

Further, a part of the bottom (i.e., a bottom surface) of the second trench 3b does not have a rounded shape. In other words, the part of the bottom (i.e., the bottom surface) of the second trench 3b has a shape without a curvature. The part of the bottom extends in a direction in parallel to the direction perpendicular to the depth direction of the trench 3 (i.e., a right-left direction of the drawing in FIG. 4).

The cavity portion 6 is formed in the gate electrode 5 to have a shape along the sidewall of the second trench 3b. Specifically, the cavity portion 6 is formed to have an ellipsoidal shape in a cross section, which extends in the depth direction of the trench 3.

The above semiconductor device is manufactured as follows.

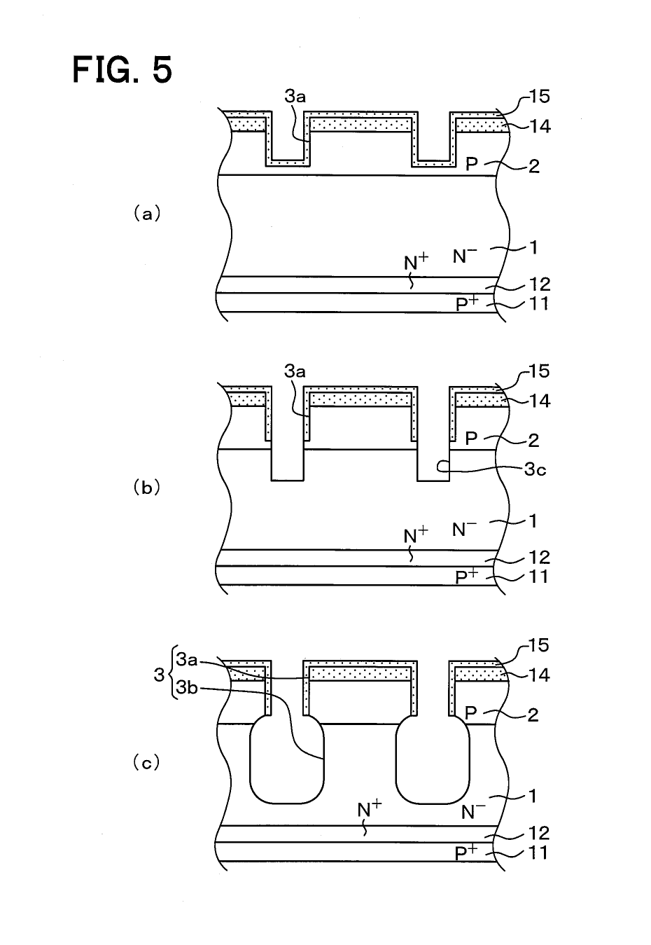

Specifically, as shown in FIG. 5(a), the steps similar to FIGS. 2(a) to 2(c) are performed, and the first trench 3a is formed. After that, the etching mask 14 made of a SiN film or the like is formed on the sidewall of the first trench 3a by the CVD method or the like.

Then, as shown in FIG. 5(b), the anisotropic etching such as the RIE is performed on the bottom of the first trench 3a, so that the etching mask 14 arranged on the bottom of the first trench 3a is removed, and further, the third trench 3c is formed to reach the drift layer 1. Here, since the third trench 3c is formed by the anisotropic etching, the distance between facing sidewalls is constant.

Next, as shown in FIG. 5(c), the isotropic etching is performed on the third trench 3c, so that the facing sidewalls of the third trench 3c are set back. Thus, the second trench 3b is formed. In this case, since the second trench 3b is formed such that a part of the sidewall and a part of the bottom of the third trench 3c are set back isotropically, the part of the sidewall and a part of the bottom of the third trench 3c has a shape without being rounded.

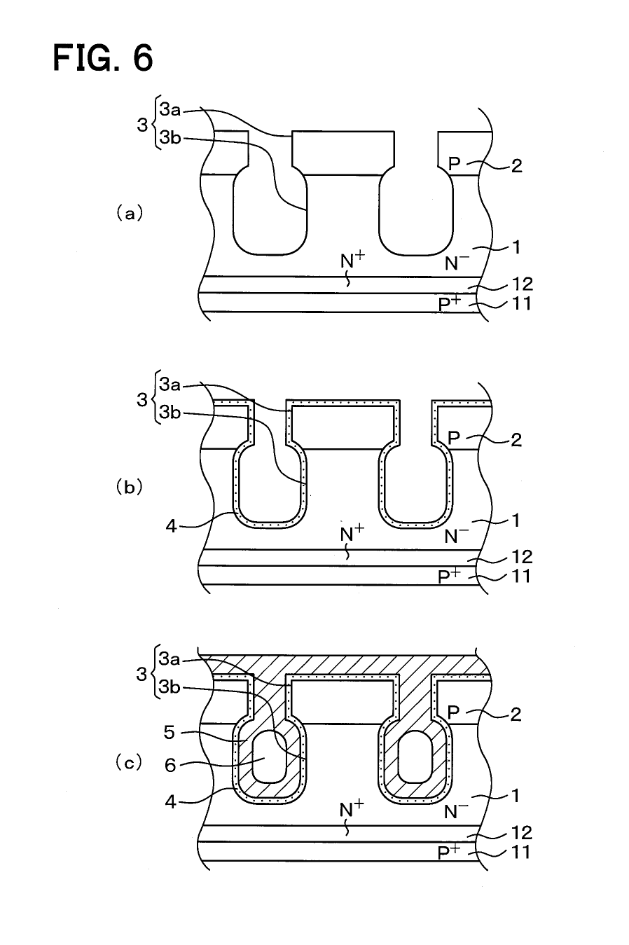

After that, similar to the first embodiment, as shown in FIG. 6(a), the etching masks 14, 15 are removed. Then, as shown in FIG. 6(b), the gate insulation film 4 is formed.

After that, as shown in FIG. 6(c), the conductive material such as doped poly silicon is deposited by the CVD method, so that the gate electrode 5 having the cavity portion 6 inside the gate electrode 5 is formed, and the cavity portion 6 has the shape along the sidewall of the second trench 3b.

As described above, in the semiconductor device according to the present embodiment, the second trench 3b has the length in the depth direction of the trench 3, which is elongated. Accordingly, the region of the drift layer 1 arranged between adjacent second trenches 3b is enlarged, and further, the hole accumulated in the drift layer 1 is difficult to be discharged via the base layer 2. Accordingly, the on-state resistance is much reduced, and the effects similar to the first embodiment are obtained.

### Third Embodiment

A third embodiment of the present disclosure will be explained. In the present embodiment, the shape of the cavity portion 6 is changed, compared with the first embodiment. Other features are similar to the first embodiment, and therefore, the other features are not explained here.

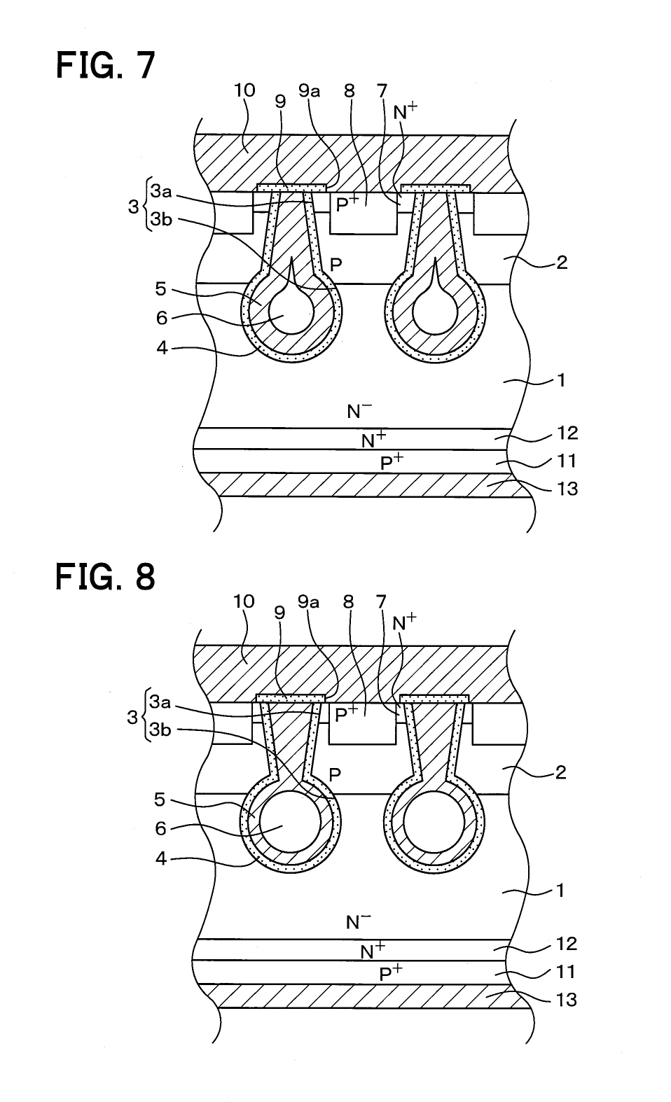

As shown in FIG. 7, in the semiconductor device according to the present embodiment, the first trench 3a has an inverse tapered shape so that the distance between facing sidewalls is shortened toward the opening. Further, the cavity portion 6 is formed from the second trench 3b to the first trench 3a. The distance between facing sidewalls of the first trench 3a is large, compared with a case where the distance between facing sidewalls near the connection portion between the first trench 3a and the second trench 3b is constant. Here, a part of the cavity portion 6 disposed in the second trench 3b according to the present embodiment also has the shape along the sidewall of the second trench 3b.

The above semiconductor device is manufactured as follows.

Specifically, when the first trench 3a is formed at the step in FIG. 2(b), for example, a mixture ratio of gasses for providing the etching gas is controlled when the etching is performed, so that the first trench 3a having the inverse tapered shape is formed. Specifically, when the first trench 3a is formed using the etching gas including SF₆ (sulfur hexafluoride) and oxygen (O₂), the ratio of SF₆ (sulfur hexafluoride) for increasing the etching of the sidewall is increased as the etching progresses, so that the first trench 3a having the inverse tapered shape is formed.

When the gate electrode 5 is formed at the step in FIG. 3(d), the conductive material such as doped poly silicon is deposited by the CVD method. In this case, since the first trench 3a has the inverse tapered shape, the opening of the first trench 3a is sealed before a part of the first trench 3a disposed on the second trench 3b side is completely filled. Accordingly, the cavity portion 6 disposed from the second trench 3b to the first trench 3a is formed.

In the above case, since the cavity portion 6 is formed to be disposed from the second trench 3b to the first trench 3a, the cavity portion 6 further reduces the stress. Accordingly, the deterioration of the characteristics of the trench gate structure and the reduction of the reliability are much restricted.

### Fourth Embodiment

A fourth embodiment of the present disclosure will be explained. In the present embodiment, the shape of the cavity portion 6 is changed, compared with the first embodiment. Other features are similar to the first embodiment, and therefore, the other features are not explained here.

As shown in FIG. 8, in the semiconductor device according to the present embodiment, the first trench 3a has a tapered shape such that the distance between the facing sidewalls is elongated toward the opening. The gate electrode 5 fills the first trench 3a without any space.

The above semiconductor device is manufactured as follows.

Specifically, when the first trench 3a is formed at the step in FIG. 2(b), for example, a mixture ratio of gasses for providing the etching gas is controlled when the etching is performed, so that the first trench 3a having the tapered shape is formed. Specifically, when the first trench 3a is formed using the etching gas including SF₆ (sulfur hexafluoride) and oxygen (O₂), the ratio of SF₆ (sulfur hexafluoride) for increasing the etching of the sidewall is decreased as the etching progresses, so that the first trench 3a having the tapered shape is formed.

When the gate electrode 5 is formed at the step in FIG. 3(d), the conductive material such as doped poly silicon is deposited by the CVD method. In this case, since the first trench 3a has the tapered shape, the doped poly silicon is completely embedded in the first trench 3a without any space.

In the above case, since the first trench 3a has the tapered shape, the doped poly silicon is completely embedded in the first trench 3a without any space. Thus, the break strength of the gate electrode 5 is secured, and the cavity portion 6 is formed in the second trench 3b.

### Other Embodiments

In each of the above embodiments, an example is explained such that the first conductive type is the N conductive type, and the second conductive type is the P conductive type. Alternatively, the first conductive type may be the P conductive type, and the second conductive type may be the N conductive type.

In each embodiment, an example is explained such that the IGBT is formed in the semiconductor device. Alternatively, the present disclosure may be applied to the semiconductor device, in which the MOSFET without forming the collector layer 11 is formed. Further, in each embodiment, the vertical type semiconductor device, in which the current flows in the thickness direction of the drift layer 1, is explained. Alternatively, the present disclosure may be applied to a lateral type semiconductor device, in which the current flows in the planar direction of the drift layer 1. Specifically, for example, when the present disclosure is applied to the semiconductor device, in which the IGBT is formed, the collector layer 11 is formed in a surface portion of the drift layer 1, which is spaced apart from the base layer 2.

Further, in each embodiment, the manufacturing method of the semiconductor device is explained such that the base layer 2 is formed in the surface portion of the drift layer 1, and the collector layer 11 and the buffer layer 12 are formed on the backside of the drift layer 1. Alternatively, the following manner may be acceptable. Specifically, the substrate for providing the drift layer 1 is prepared, and the trench gate structure is formed. Then, the base layer 2 and the collector layer 11 and the like are formed.

While the present disclosure has been described with reference to embodiments thereof, it is to be understood that the disclosure is not limited to the embodiments and constructions. The present disclosure is intended to cover various modification and equivalent arrangements. In addition, while the various combinations and configurations, other combinations and configurations, including more, less or only a single element, are also within the spirit and scope of the present disclosure.

1. A semiconductor device comprising:
a drift layer having a first conductive type;
a base layer having a second conductive type and arranged in a surface portion of the drift layer;
a plurality of trenches penetrating the base layer, reaching the drift layer, and arranged in a predetermined direction;
a gate insulation film arranged on a sidewall of each trench; and
a gate electrode arranged on the gate insulation film, respectively,
wherein each trench includes:
a first trench having an opening on a surface of the base layer; and
a second trench connecting the first trench and having a portion, of which a distance between facing sidewalls of the second trench is longer than a distance between facing sidewalls of the first trench,
wherein the opening of each first trench is sealed with the gate electrode, and
wherein an inside of each gate electrode includes a cavity portion.

2. The semiconductor device according to claim 1,
wherein each cavity portion has a shape along the sidewall of the second trench, and
wherein each cavity portion is disposed in the second trench.

3. The semiconductor device according to claim 1,
wherein the first trench has a tapered shape that a distance between facing sidewalls at the opening is longer than a distance between facing sidewalls at a connection portion between the first trench and the second trench, and
wherein each cavity portion is only disposed in the second trench.

4. The semiconductor device according to claim 1,
wherein the first trench has a tapered shape that a distance between facing sidewalls at the opening is shorter than a distance between facing sidewalls at a connection portion between the first trench and the second trench, and
wherein each cavity portion is disposed from the second trench to the first trench.
